(19) United States
(12) Patent Application Publication
(10) Pub. No.: US 2010/0244062 A1
(43) Pub. Date: Sep. 30, 2010

(54) WHITE LIGHT EMITTING ELEMENT

(75) Inventor: Shigehiro Ueno, Shinjuku-Ku (JP)

Correspondence Address: BURR & BROWN, PO BOX 7068, SYRACUSE, NY, 13261-7068, US

(73) Assignee: Dai Nippon Printing Co., Ltd., Shinjuku-Ku (JP)

(21) Appl. No.: 12/680,058

(22) PCT Filed: Sep. 29, 2008
(86) PCT No.: PCT/JP2008/067670

§ 371 Date: May 21, 2010

(30) Foreign Application Priority Data
Sep. 28, 2007 (JP) 2007-256876

(51) Int. Cl. H01L 33/02

(52) U.S. Cl. 257/90; 977/773; 257/E33.012

(57) ABSTRACT

This invention provides a white light emitting element having a prolonged lifetime that can emit white light having high color purity. The white light emitting element comprises: opposed electrodes 3, 4; a luminescent layer A comprising an organic material and/or inorganic nanoparticles that emit light by EL; a luminescent layer B comprising inorganic nanoparticles that emit light by PL; and opposed reflective layers 5, 6 that allow light generated in the luminescent layer A to resonate within the element, light generated in the luminescent layer A and light generated in the luminescent layer B together producing white light, wherein one of the opposed electrodes 3, 4 or a layer adjacent to the electrodes has a total reflection function and is provided as one of the reflective layers, and the other electrode or a layer adjacent to the other electrode has a semi-transparent reflection function and is provided as the other reflective layer.

### CROSS-REFERENCE TO RELATED APPLICATIONS

This application is based upon and claims the benefit of priority under Article 4 of the Paris Convention from the prior Japanese Patent Applications No. 256876/2007, filed on Sep. 28, 2007, the entire contents of the specifications, drawings, etc. of which are incorporated herein by reference.

### FIELD OF INVENTION

The present invention relates to a white light emitting element and more specifically relates to a white light emitting element that can easily regulate color, can emit white light by spectral components of R, G, and B having high color purity, and has a prolonged lifetime.

### BACKGROUND ART

Light emitting devices using semiconductor fine particles, the luminescent color of which can be regulated by the particle diameter, as a luminescent material that emits light by a photoluminescence phenomenon (hereinafter referred to as “PL luminescence”) (this luminescent material being hereinafter referred to as “PL material”) (see, for example, patent document 1: Japanese Translation of PCT Publication No. 510866/2005) and light emitting devices using semiconductor fine particles, the luminescent color of which can be regulated by the particle diameter, as a luminescent material that emits light by electroluminescence (hereinafter referred to as “EL luminescence”) (this luminescent material being hereinafter referred to as “EL material”) (see, for example, patent document 2: Japanese Translation of PCT Publication No. 522005/2005) have been proposed. These documents exemplify as a representative example semiconductor fine particles comprising a core of CdSe, a ZnS shell provided on the outer periphery of the core, and a capping compound provided on the outer periphery of the ZnS shell.

On the other hand, patent document 3 (Japanese Patent Application Laid-Open No. 115884/2007) proposes an organic EL light emitting element comprising an anode and a cathode, one of which is a light transparent electrode and the other a reflective electrode, and an organic layer which is held between both the electrodes and a part of which is provided as an organic EL luminescent layer, the other part of the organic layer being constructed so as to contain a PL material. In this organic EL light emitting element, for example, the organic EL material contained in the organic EL luminescent layer emits blue light, and the PL material excited by the blue light emits other color (for example, red light and green light) to control the luminescent color radiated into the outside of the element.

### DISCLOSURE OF INVENTION

In the organic EL light emitting element, research has been made with prolongation of the lifetime as an important technical task. In this regards, in the organic EL light emitting element disclosed in patent document 3, since only an organic EL material that emits blue light is used, the prolongation of the lifetime can be easily realized. On the other hand, since one of the electrodes is used as a reflective electrode, it has been regarded that the efficiency of outgoing from the light transparent electrode side to the outside of the element can be increased to enhance the external quantum efficiency.

In the organic EL light emitting element of patent document 3, however, it is described that white light can be produced from blue light emitted from the EL material and red light and green light emitted from the PL material. Luminescence spectra of a number of organic fluorescent materials and phosphorescent materials, however, are broad and have poor color purity. Further, it is easily considered that, for some organic PL materials adopted, color is gradually shifted from white light by a PL luminescence drive deterioration of the organic PL material. Furthermore, it is easily expected that the color purity of each of the R, G, and B spectral components constituting the white light spectrum is poor.

The present invention has been made with a view to solving the above problems, and the present invention is to provide a white light emitting element having a prolonged lifetime that can easily regulate color and can produce white light by R, G, and B spectral components having high color purity.

The invention can be attained by a white light emitting element comprising opposed electrodes; a luminescent layer A comprising an organic material and/or inorganic nanoparticles that emit light by electroluminescence (EL); a luminescent layer B comprising inorganic nanoparticles that emit light by photoluminescence (PL); and opposed reflective layers that allow light emitted in the luminescent layer A to resonate within the element, light emitted in the luminescent layer A and light emitted in the luminescent layer B together producing white light, characterized in that one of the opposed electrodes or a layer adjacent to the electrodes has a total reflection function and is provided as one of the reflective layers, and the other electrode or a layer adjacent to the other electrode has a semi-transparent reflection function and is provided as the other reflective layer.

According to the present invention, one of the electrodes or a layer adjacent to the electrodes has a total reflection function and is provided as one of the reflective layers, and the other electrode or a layer adjacent to the other electrode has a semi-transparent reflection function and is provided as the other reflective layer. Therefore, light emitted in the luminescent layer A comprising an organic material and/or inorganic nanoparticles by EL luminescence can be resonated between the layer having the total reflection function and the layer having the semi-transparent reflection function to reduce the half-value width of the luminescence spectrum. It is generally said that the organic EL luminescence and the organic PL luminescence have luminescence spectra having a broad half-value width and the inorganic EL luminescence and the inorganic PL luminescence have luminescence spectra having a narrow half-value width. In the present invention, however, the half-value width of the luminescence spectrum in the EL luminescence of the organic EL material in the luminescent layer A can be narrowed. Accordingly, when white light is produced by lights emitted from the respective luminescences, the color purity of each of the spectral components of R, G, and B constituting the white luminescence spectrum can be enhanced.

According to the present invention, unlike the prior art technique, an EL material of three primary colors of RGB is not contained in the luminescent layer A, and, further, an inorganic PL material comprising stable inorganic nanoparticles is contained in the luminescent layer B. Accordingly, the color of the white light can easily be adjusted, for example, by regulating, for example, the content of the PL material contained in the luminescent layer B or regulating the reflectance of the layer having the semi-transparent reflection function or the distance between the layer having the semi-transparent reflection function and the electrode having the total reflection function. Further, since a single color of a blue organic EL material having a prolonged lifetime is used while other colors, are emitted by stable inorganic PL materials, the lifetime of the whole element can be prolonged, and, further, color shifting caused by the movement of luminescence sites due to a driving-derived deterioration can also be suppressed.

In a preferred embodiment of the white light emitting element according to the present invention, the electrode or adjacent layer having the semi-transparent reflection function is provided to change a luminescence spectrum of light emitted from the luminescent layer A to a luminescence spectrum having a narrower half-value width.

According to the present invention, as described above, light emitted by EL luminescence in the luminescent layer A can be resonated between the layer having the total reflection function and the layer having the semi-transparent reflection function to reduce the half-value width of the luminescence spectrum. However, the half-value width of the luminescence spectrum can be reduced, for example, by regulating the relationship of the optical distance between the opposed reflective layers with the wavelength of light emitted by EL luminescence, and the color purity of the color component emitted in the luminescent layer A can be improved.

In a preferred embodiment of the white light emitting element according to the present invention, the luminescent layer A comprises an organic material that emits blue light and/or inorganic nanoparticles that emit blue light, and the luminescent layer B comprises inorganic nanoparticles that emit red light and inorganic nanoparticles that emit green light. Further, in a preferred embodiment of the white light emitting element according to the present invention, the luminescent layer A comprises an organic material that emits ultraviolet light and/or inorganic nanoparticles that emit ultraviolet light, and the luminescent layer B comprises inorganic nanoparticles that emit blue light, inorganic nanoparticles that emit red light, and inorganic nanoparticles that emit green light. In any of these embodiments, the half-value width of the luminescence spectrum can be narrowed, and white light having a high color purity can be provided.

In a preferred embodiment of the white light emitting element according to the present invention, the inorganic nanoparticles are semiconductor fine particles, the luminescent color of which can be regulated by the particle diameter, and/or dopant-containing semiconductor fine particles. The semiconductor fine particles, the luminescence color of which can be regulated by the particle diameter, are also called quantum dots, nanoparticles, or nanocrystals.

In a preferred embodiment of the white light emitting element according to the present invention, the luminescent layer A and the luminescent layer B each have a single layer structure or a multilayer structure.

According to this invention, the luminescent layer A and the luminescent layer B each may have a single-layer structure or a multilayer structure of two or more. Accordingly, for example, individual layers containing PL materials of a plurality of respective colors to be included in the luminescent layer B can be individually formed, and, thus, the production process can easily be carried out.

In a preferred embodiment of the white light emitting element according to the present invention, when the reflective layer having the semi-transparent reflection function is provided as a layer adjacent to the electrode, the electrode and the reflective layer are provided through the luminescent layer B and, further, the reflective layer is provided on the light outgoing surface side of the electrode. For example, the electrode having the reflection function, the luminescence layer A, the electrode, the luminescent layer B, and the reflective layer having the semi-transparent reflection function are formed in that order.

According to the present invention, also when the luminescent layer B is disposed outside between the opposed electrodes, the PL materials contained in the luminescent layer B can be excited and exhibit luminescence by light emitted by EL luminescence from the luminescence layer A. Also in this case, light emitted by EL luminescence from the luminescent layer A is resonated between the opposed reflective layers and exhibits a luminescence spectrum having a narrow half-value width, and, thus, the color purity of the color component of light emitted from the luminescent layer A can be improved.

In a preferred embodiment of the white light emitting element according to the present invention, one or more layers of the reflective layer having the semi-transparent reflection function may be provided between the opposed electrodes and/or outside the electrodes. Further, the electrode or adjacent layer having the semi-transparent reflection function may be provided so as not to reduce the emission of light from the luminescent layer B.

In a preferred embodiment of the white light emitting element according to the present invention, the white light emitting element has a top emission-type element structure or a bottom emission-type element structure that takes out the white light from the white light emitting element on its side where the layer having the semi-transparent reflection function is provided.

According to the white light emitting element of the present invention, light emitted by EL luminescence in the luminescent layer A can be resonated between the layer having the total reflection function and the layer having the semi-transparent reflection function to reduce the half-value width of the luminescence spectrum. Accordingly, the color purity of the spectral components of R, G, and B constituting the white luminescence spectrum can be enhanced by producing white light using lights emitted from both the luminescent layer A and the luminescent layer B. Further, according to the white light emitting element of the present invention, the color of the white light having high color purity can easily be adjusted, for example, by regulating, for example, the content of the PL material contained in the luminescent layer B or regulating the reflectance of the layer having the semi-transparent reflection function or the distance between the layer having the semi-transparent reflection function and the electrode having the total reflection function. Further, since the color of the EL material having a task of prolonging the lifetime is only one and blue while other colors are emitted by stable PL materials, the lifetime of the whole element can be prolonged, and, further, color shifting caused by the movement of luminescence sites due to a driving-derived deterioration can also be suppressed.

The white light emitting element according to the present invention can be used as a white light source panel such as lighting, as an RGB light emitting panel that has a broad color reproduction range and has a high luminescence efficiency through a combination with a color filter, or as a backlight for LCD-OLED or LCD-LED. The white light emitting element according to the present invention advantageously can realize a reduction in the thickness of the color filter by virtue of a high color purity of the spectral components of R, G, and B constituting the white light luminescence spectrum and can improve light use efficiency because the proportion of light cut by the filter can be reduced.

### BRIEF DESCRIPTION OF DRAWINGS

FIG. 1 is a typical cross-sectional view showing a basic element structure of a white light emitting element according to the present invention.

FIG. 2 is a typical cross-sectional view showing an embodiment of a white light emitting element having a bottom emission-type element structure.

FIG. 3 is a typical cross-sectional view showing an embodiment of a white light emitting element having a top emission-type element structure.

FIG. 4 is a typical cross-sectional view showing another embodiment of a white light emitting element having a top emission-type element structure.

FIG. 5 is a typical diagram showing an embodiment of a white light emitting element having a bottom emission-type element structure in which a part or the whole of a luminescent layer B is provided outside between opposed electrodes.

FIG. 6 is a typical diagram showing an embodiment of a white light emitting element having a top emission-type element structure in which a part or the whole of the luminescent layer B is provided outside between opposed electrodes.

FIG. 7 is a graph showing a luminescence spectrum obtained from the white light emitting element of Example 1 and a luminescence spectrum for only a blue luminescent material used in the luminescent layer A in Example 1.

### DESCRIPTION OF REFERENCE CHARACTERS

1, 1A to 1Q White light emitting element
2, 2′ Substrate
3 Anode
4 Cathode
5 Semi-transparent reflective layer
6 Reflective layer
7 Electron transport layer
8 Electron injection layer
9 Hole transport layer
10 Passivation layer
11 Protecting layer
21, 22 Inorganic nanoparticles

### DETAILED DESCRIPTION OF THE INVENTION

Embodiments of the white light emitting element according to the present invention will be described. However, it should be noted that the present invention is not to be construed as being limited to the following embodiments and the accompanying drawings.

[Basic Construction]

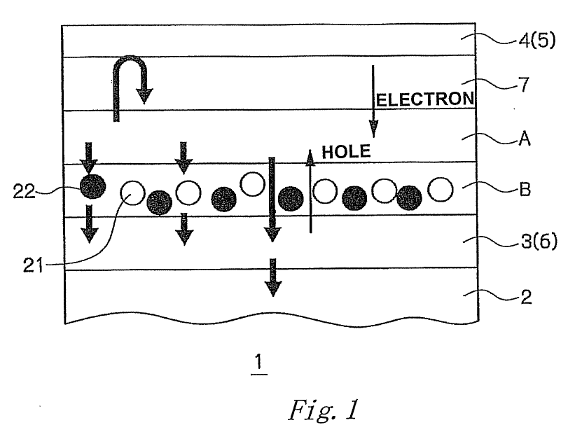

FIG. 1 is a typical cross-sectional view showing a basic element structure of a white light emitting element according to the present invention. As shown in FIG. 1, a white light emitting element 1 according to the present invention comprises opposed electrodes 3, 4; a luminescent layer A comprising an organic material and/or inorganic nanoparticles, as an EL material, that emit light by electroluminescence (EL); a luminescent layer B comprising inorganic nanoparticles, as a PL material, that emit light by photoluminescence (PL); and opposed reflective layers 5, 6 that allow light generated in the luminescent layer A to resonate within the element, light generated in the luminescent layer A and light generated in the luminescent layer B together producing white light.

The white light emitting element is characterized in that one of the opposed electrodes 3, 4 or a layer adjacent to the electrodes 3, 4 has a total reflection function and is provided as one of the reflective layers, and the other electrode or a layer adjacent to the other electrode has a semi-transparent reflection function and is provided as the other reflective layer.

In the white light emitting element 1 according to the present invention, when voltage is applied across opposed electrodes (an anode 3 and a cathode 4) to generate an electric field in the luminescent layer A containing an EL material, the EL material contained in the luminescent layer A exhibits EL luminescence and consequently emits blue light or ultraviolet light. As shown in FIG. 1, the blue light or the ultraviolet light travels toward the anode 3 and cathode 4 sides, is reflected from each of the electrodes that function as a semi-transparent reflective layer or a total reflection layer or a layer adjacent to the electrodes, undergoes an action of the so-called resonator structure, and is then radiated through a light outgoing surface which is on the total reflective layer-free side (that is, the side where the semi-transparent reflective layer is provided) into the outside of the element. In this case, when the blue light or the ultraviolet light reflected within the resonator structure has a wide half-value width in the luminescence spectrum and is poor in the so-called color purity, the half-value width can be reduced by the resonator structure and, consequently, the color purity can be improved. Further, in the white light emitting element according to the present invention, the luminescent layer B contains a PL material having higher color purity than the EL material. Accordingly, the blue light or the ultraviolet light emitted in the luminescent layer A allows the PL materials contained in the luminescent layer B to emit light. Spectral components of R, G, and B constituting the white light spectrum can produce light having a very high color purity by adopting PL materials that emit red light and green light when blue light is emitted in the luminescent layer A, or by adopting PL materials that emit red light, green light, and blue light when ultraviolet light is emitted in the luminescent layer A.

Accordingly, in the white light emitting element according to the present invention, unlike the prior art technique, EL materials of three primary colors of RGB are not incorporated in the luminescent layer A, and stable PL materials are incorporated in the luminescent layer B. Therefore, the color of the white light can easily be adjusted, for example, by regulating, for example, the content of the PL material contained in the luminescent layer B or regulating the reflectance of the layer having the semi-transparent reflection function or the distance between the layer having the semi-transparent refection function and the electrode having the total reflection function. Further, since a single color of a blue organic EL material having a prolonged lifetime is used while other colors are emitted by stable inorganic PL materials, the lifetime of the whole element can be prolonged, and, further, color shifting caused by the movement of luminescence sites due to a change in carrier injection or transportability from the initial state by a driving-derived deterioration can also be reduced. The color shifting due to a driving-derived deterioration causes a change in color balance of the white light emitting element over time and thus is one of factors that inhibit the practical use of the white light emitting element. The present invention, however, can advantageously stabilize the color balance over time.

### EMBODIMENTS

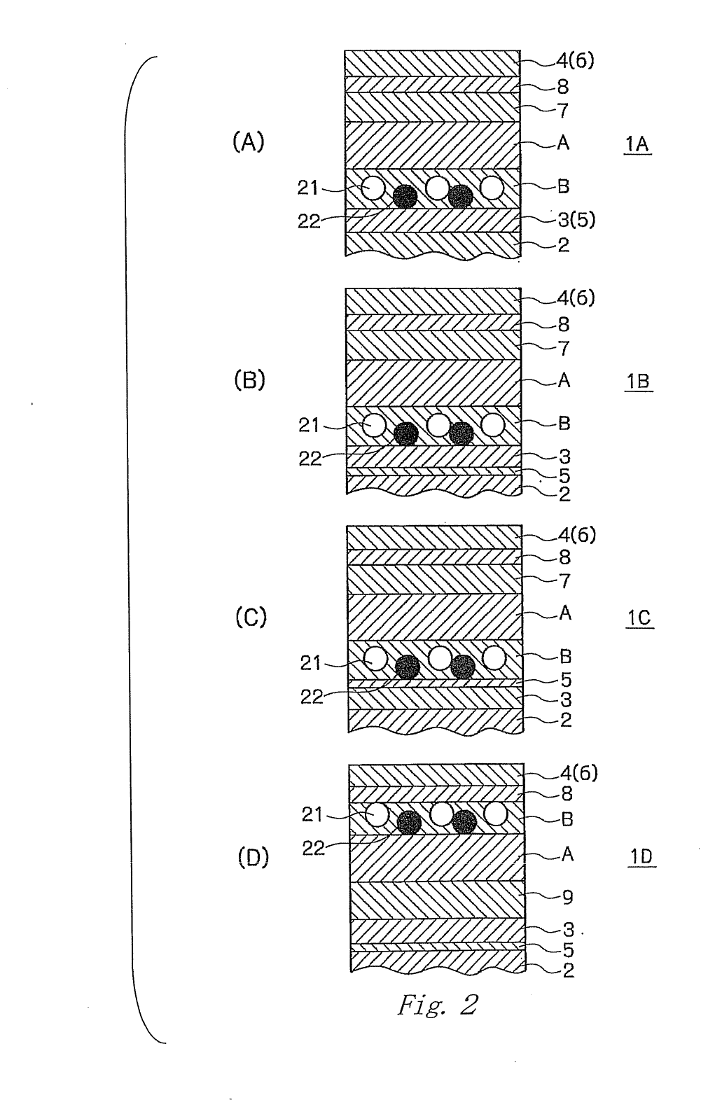

Various embodiments of the white light emitting element according to the present invention will be described in detail with reference to FIGS. 2 to 6. The layer having the semi-transparent reflection function refers to a semi-transparent reflective layer 5, and the layer having the total reflection function refers to a total reflective layer 6.

FIG. 2 is a typical cross-sectional view showing an embodiment of a white light emitting element having a bottom emission-type element structure.

A white light emitting element 1A shown in FIG. 2 (A) is an embodiment of a white light emitting element according to the present invention that comprises a transparent substrate 2, an anode 3 that functions also as a semi-transparent reflective layer 5, a luminescent layer B that contains a PL material 21 which emits red light within a hole transport material and a PL material 22 which emits green light, a luminescent layer A that contains an EL material (not shown) which emits blue light, an electron transport layer 7, an electron injection layer 8, and a cathode 4 that functions also as a total reflective layer 6, stacked in that order as viewed from the transparent substrate 2 side.

FIG. 2 (B) shows a white light emitting element 1B that is an embodiment of a white light emitting element according to the present invention and has the same construction as the white light emitting element 1A shown in FIG. 2 (A), except that, instead of the anode 3 which functions also as a semi-transparent reflective layer 5, a semi-transparent reflective layer 5 and a transparent anode 3 are provided in that order.

FIG. 2 (C) shows a white light emitting element 1B that is an embodiment of a white light emitting element according to the present invention and has the same construction as the white light emitting element 1A shown in FIG. 2 (A), except that, instead of the anode 3 which functions also as a semi-transparent reflective layer 5, a transparent anode 3 and a semi-transparent reflective layer 5 are provided in that order.

FIG. 2 (D) shows a white light emitting element 1D that is an embodiment of a white light emitting element according to the present invention and has the same construction as the white light emitting element 1B shown in FIG. 2 (B), except that a hole transport layer 9 free from the PL material is provided instead of the luminescent layer B, and a luminescent layer B comprising an electron transport material, a PL material 21 which emits red light and a PL material 22 which emits green light, the PL material 21 and the PL material 22 being incorporated in the electron transport material, is provided instead of the electron transport layer 7.

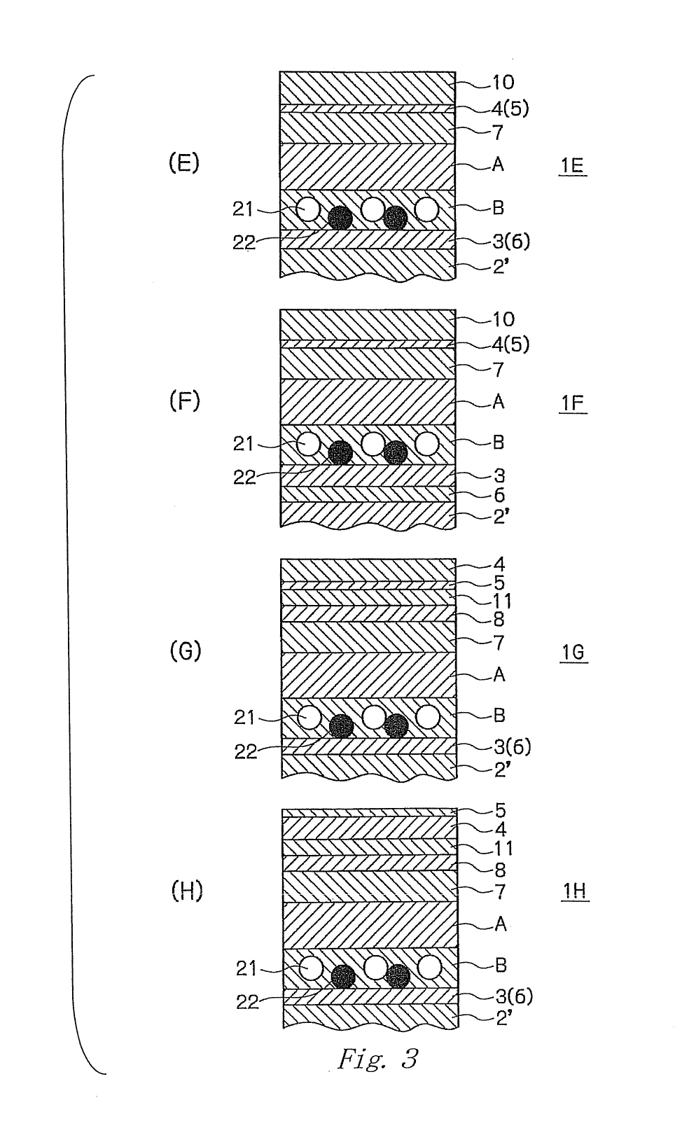

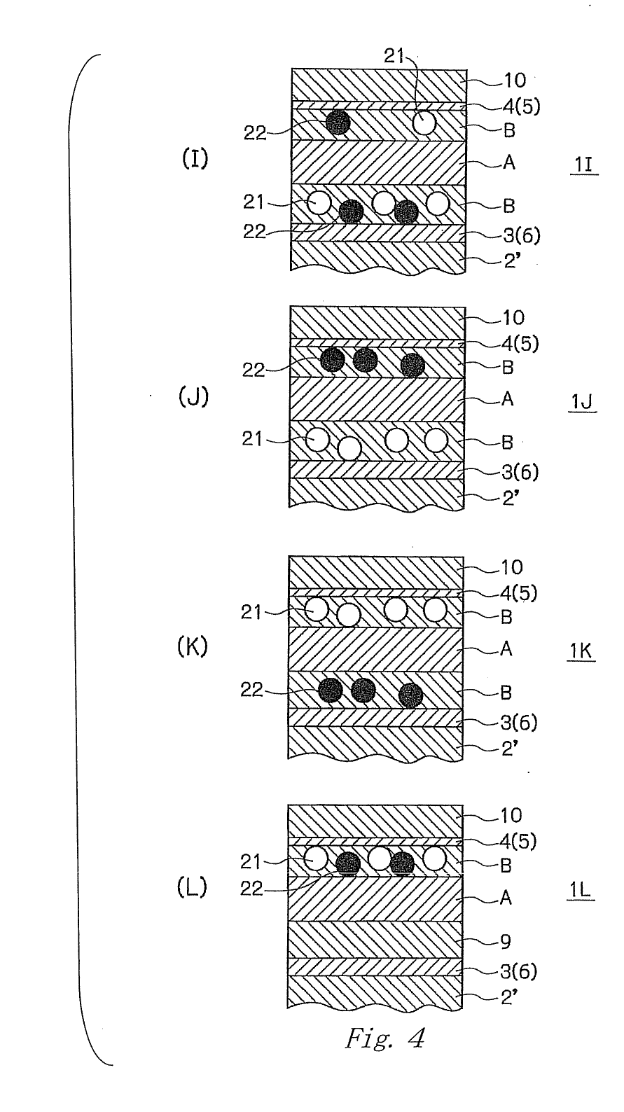

FIGS. 3 and 4 each are a typical cross-sectional view showing an embodiment of a white light emitting element having a top emission-type element structure.

A white light emitting element 1E shown in FIG. 3 (E) is an embodiment of a white light emitting element according to the present invention that comprises a substrate that is not always required to be transparent (hereinafter indicated by “substrate 2′”), an anode 3 that functions also as a total reflective layer 6, a luminescent layer B comprising a hole transport material, a PL material 21 which emits red light and a PL material 22 which emits green light, the PL material 21 and the PL material 22 being incorporated in the hole transport material, a luminescent layer A comprising an EL material that emits blue light (not shown), an electron transport layer 7, a cathode 4 that functions also as a semi-transparent reflective layer 5, and a passivation layer 10 impermeable to water vapor and oxygen, stacked in that order as viewed from the substrate 2′ side.

FIG. 3 (F) shows a white light emitting element 1F that is an embodiment of a white light emitting element according to the present invention and has the same construction as the white light emitting element 1E shown in FIG. 3 (E), except that, instead of the anode 3 which functions also as a total reflective layer 6, a total reflective layer 6 and a transparent anode 3 are provided in that order.

FIG. 3 (G) shows a white light emitting element 1G that is an embodiment of a white light emitting element according to the present invention and has the same construction as the white light emitting element 1E shown in FIG. 3 (E), except that, instead of the semi-transparent reflective layer 5 and the passivation layer 10 provided on the electron transport layer 7, an electron injection layer 8, a protecting layer 11 formed by sputtering or the like, a semi-transparent reflective layer 5, and a transparent cathode 4 are provided in that order.

FIG. 3 (H) shows a white light emitting element 1H that is an embodiment of a white light emitting element according to the present invention and has the same construction as the white light emitting element 1E shown in FIG. 3 (E), except that, instead of the semi-transparent reflective layer 5 and the passivation layer 10 provided on the electron transport layer 7, an electron injection layer 8, a protecting layer 11 formed by sputtering or the like, a transparent cathode 4, and a semi-transparent reflective layer 5 are provided in that order.

FIG. 4 (I) shows a white light emitting element 1I that is an embodiment of a white light emitting element according to the present invention and has the same construction as the white light emitting element 1E shown in FIG. 3 (E), except that the luminescent layer B is provided on the upper part and the lower part of the luminescent layer A. Specifically, the white light emitting element it comprises a substrate 2′, an anode 3 that functions also as a total reflective layer 6, a luminescent layer B comprising a hole transport material, a PL material 21 which emits red light and a PL material 22 which emits green light, the PL material 21 and the PL material 22 being incorporated in the hole transport material, a luminescent layer A comprising an EL material which emits blue light (not shown), a luminescent layer B comprising an electron transport material, a PL material 21 which emits red light and a PL material 22 which emits green light, the PL material 21 and the PL material 22 being incorporated in the electron transport material, a cathode 4 that functions also as a semi-transparent reflective layer 5, and a passivation layer 10 impermeable to water vapor and oxygen, stacked in that order as viewed from the substrate 2′ side.

FIG. 4 (J) shows a white light emitting element 1J that is an embodiment of a white light emitting element according to the present invention and has the same construction as the white light emitting element 1I shown in FIG. 4 (I), except that the lower luminescent layer B contains only the PL material 22 which emits green light, and the upper luminescent layer B contains only the PL material 21 which emits red light.

FIG. 4 (K) shows a white light emitting element 1K that is an embodiment of a white light emitting element according to the present invention and has the same construction as the white light emitting element 1I shown in FIG. 4 (I), except that the lower luminescent layer B contains only the PL material 21 which emits red light, and the upper luminescent layer B contains only the PL material 22 which emits green light.

FIG. 4 (L) shows a white light emitting element 1L that is an embodiment of a white light emitting element according to the present invention and has the same construction as the white light emitting element 1I shown in FIG. 4 (I), except that a hole transport layer 9 free from the PL material is provided instead of the lower luminescent layer B.

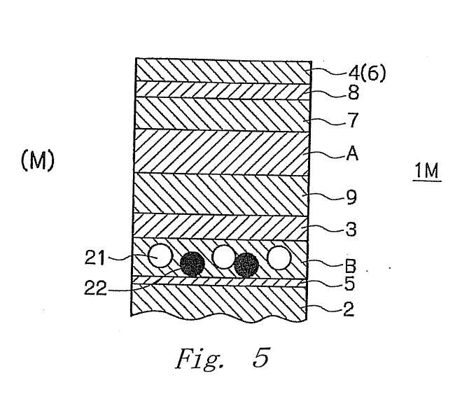

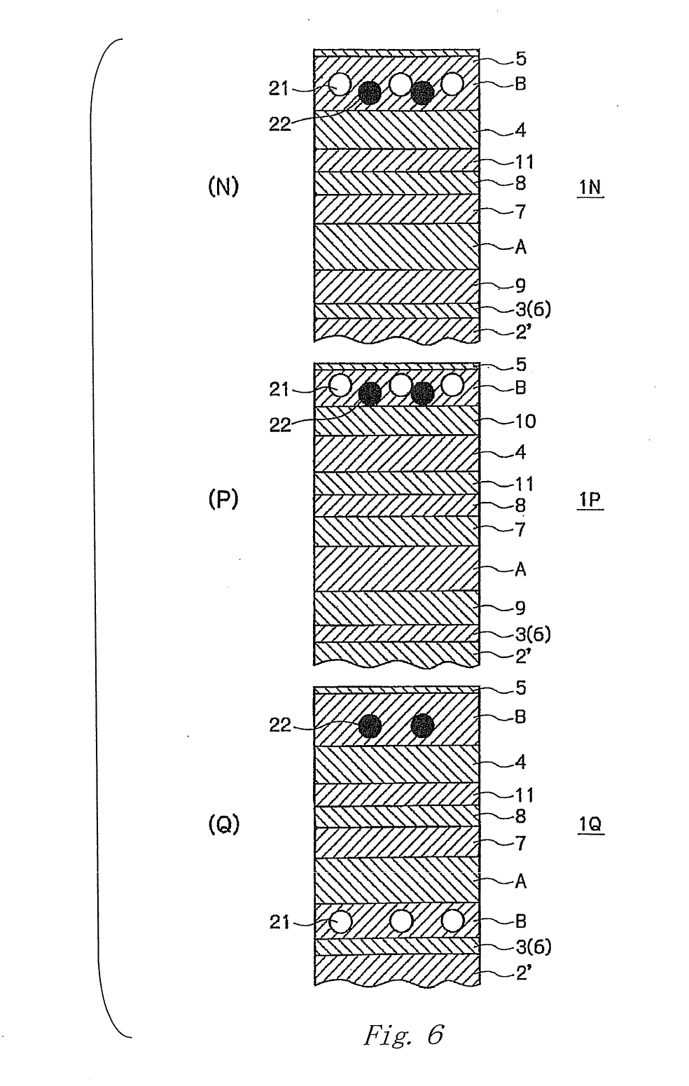

FIGS. 5 and 6 are typical diagrams showing embodiments of a white light emitting element having an element structure in which a part or the whole of the luminescent layer B is provided outside between the opposed electrodes. FIG. 5 shows a white light emitting element having a bottom emission-type element structure, and FIG. 6 a white light emitting element having a top emission-type element structure.

FIG. 5 shows a white light emitting element 1M that is an embodiment of a white light emitting element according to the present invention and comprises a transparent substrate 2, a semi-transparent reflective layer 5, a luminescent layer B comprising a transparent binder resin material, a PL material 21 which emits red light and a PL material 22 which emits green light, the PL material 21 and the PL material 22 being incorporated in the transparent binder resin material, a transparent anode 3, a hole transport layer 9, a luminescent layer A comprising an EL material which emits blue light (not shown), an electron transport layer 7, an electron injection layer 8, and a cathode 4 that functions also as a total reflective layer 6, stacked in that order as viewed from the transparent substrate 2 side.

FIG. 6 (N) shows a white light emitting element 1N that is an embodiment of a white light emitting element according to the present invention and comprises a substrate 2′ which is not always required to be transparent, an anode 3 that functions also as a total reflective layer 6, a hole transport layer 9, a luminescent layer A comprising an EL material which emits blue light (not shown), an electron transport layer 7, an electron injection layer 8, a protecting layer 11 formed by sputtering or the like, a transparent cathode 4, a luminescent layer B comprising a resin material, for passivation layer formation, impermeable to water vapor and oxygen, a PL material 21 which emits red light, and a PL material 22 which emits green light, the PL material 21 and the PL material 22 being incorporated in the resin material, and a cathode 4 that functions also as a semi-transparent reflective layer 5, stacked in that order as viewed from the substrate 2′ side.

FIG. 6 (P) shows a white light emitting element 1P that is an embodiment of a white light emitting element according to the present invention and has the same construction as the white light emitting element 1N shown in FIG. 6 (N), except that, instead of the luminescent layer B, a passivation layer 10 impermeable to water vapor and oxygen and a luminescent layer B comprising a transparent binder resin material, a PL material 21 which emits red light and a PL material 22 which emits green light, the PL material 21 and the PL material 22 being incorporated in the binder resin material, are provided in that order.

FIG. 6 (Q) shows a white light emitting element 1Q that is an embodiment of a white light emitting element according to the present invention and has the same construction as the white light emitting element 1N shown in FIG. 6 (N), except that a luminescent layer B comprising a hole transport material, a PL material 22 which emits green light, the PL material 22 being incorporated in the hole transport material, is provided instead of the hole transport layer 9, and a luminescent layer B comprising a resin material, for passivation layer formation, impermeable to water vapor and oxygen and a PL material 21 which emits red light, the PL material 21 being incorporated in the resin material, is provided instead of the luminescent layer B.

[Constituent Elements]

Next, the constituent elements of the white light emitting element according to the present invention will be described in more detail. Any of the following specific materials that exert an excellent effect such as an improvement in color purity by adopting a characteristic construction comprising a resonator structure particularly comprising a luminescent layer A, a luminescent layer B, a semi-transparent reflective layer 5, and a total reflective layer 6 can be applied to a white light emitting element 1 according to the present invention. However, the present invention is not construed as being limited to the following specific examples only.

(Substrate)

The substrate may be a transparent substrate 2 or a nontransparent substrate 2′. When the white light emitting element 1 has a bottom emission-type element structure (see FIGS. 1, 2, and 5), however, the substrate should be a transparent substrate 2 because the substrate exists on the white light outgoing side of the element. On the other hand, when the white light emitting element 1 has a top emission-type element structure (see FIGS. 3, 4, and 6), the substrate is not always required to be transparent and may be formed of a nontransparent material. The type of the substrate and the structure of the substrate, i.e., shape, size and thickness, are not particularly limited and may be properly determined, for example, according to the application of the light emitting element and the material of each layer stacked on the substrate. Substrates formed of various materials, for example, metals such as Al, glass, quartz, or resins may be used. Specific examples thereof include glass, quartz, polyethylene, polypropylene, polyethylene terephthalate, polyethylene naphthalate, polymethacrylate, polymethylmethacrylate, polymethylacrylate, polyester, and polycarbonate. The substrate may be in a sheet form or a continuous form, and specific examples thereof include cards, films, disks, and chips.

(Electrodes)

The anode 3 and the cathode 4 are electrodes that supply holes and electrons to the luminescent layer A comprising an EL material. In general, as shown in FIGS. 1 to 6, the anode 3 is provided on the substrate, and the cathode 4 is provided so as to face the anode 3 so that at least the luminescent layer A is held between the cathode 4 and the anode 3.

A thin film formed of, for example, a metal, an electroconductive oxide, or an electroconductive polymer is used as the anode 3. Specific examples thereof include transparent electroconductive films such as ITO (indium tin oxide), indium oxide, IZO (indium zinc oxide), SnO₂, and ZnO, large-work function metals having good hole injectability such as gold and chromium, and electroconductive polymers such as polyaniline, polyacetylene, polyalkylthiophene derivatives, and polysilane derivatives. When the anode 3 is located on the light takeout side of the element, the use of transparent electroconductive materials such as ITO (indium tin oxide), indium oxide, IZO (indium zinc oxide), SnO₂, and ZnO is preferred. The anode 3 can be formed by vacuum processes such as vacuum deposition, sputtering, and CVD or coating. The thickness of the anode 3 may vary depending, for example, upon the material used, but is preferably, for example, approximately 10 nm to 1000 nm.

A thin film formed of, for example, a metal, an electroconductive oxide, or an electroconductive polymer is used as the cathode 4. Specific examples thereof include small-work function metals having good electron injectability, for example, single metals such as aluminum and silver, magnesium alloys such as MgAg, aluminum alloys such as AILi, AlCa, and AlMg, alkali metals including Li and Ca, and alloys of the alkali metals. When the cathode 4 is located on the light takeout side of the element, the use of transparent electroconductive materials such as ITO (indium tin oxide), indium oxide, IZO (indium zinc oxide), SnO₂, and ZnO is preferred. As with the anode 3, the cathode 4 can be formed by vacuum processes such as vacuum deposition, sputtering, and CVD or coating. The thickness of the cathode 4 may vary depending, for example, upon the material used, but is preferably, for example, approximately 10 nm to 1000 nm.

(Luminescent Layer A)

The luminescent layer A is an EL luminescent layer comprising an organic material and/or inorganic nanoparticles that emit light by EL. The luminescent layer A is held between the anode 3 and the cathode 4. In the luminescent layer A, holes supplied from the anode 3 are recombined with electrons supplied from the cathode 4, and excitons generated by the recombination cause emission of light from an EL material contained in the luminescent layer A. The luminescent layer A may have a single-layer structure as shown in FIGS. 1 to 6 or alternatively may have a multilayer structure of two or more layers.

There are two embodiments about the EL material contained in the luminescent layer A. In the first embodiment, organic materials that emit blue light and/or inorganic nanoparticles that emit blue light may be mentioned as the EL material contained in the luminescent layer A. In the second embodiment, the organic material that emits ultraviolet light and/or the inorganic nanoparticles that emit ultraviolet light 3n may be mentioned as the EL material contained in the luminescent layer A.

In each of the embodiments, the EL material formed of an organic material and the EL material formed of inorganic nanoparticles each are generally contained solely or alternatively may be simultaneously contained. The first embodiment and the second embodiment are different from each other in that, in the first embodiment, the luminescent layer A emits blue light which causes the emission of red light and green light from the PL materials contained in the luminescent layer B, resulting in the production of white light, whereas, in the second embodiment, the luminescent layer A emits ultraviolet light which causes the emission of lights from the R (red) light-emitting PL material, the G (green) light-emitting PL material, and the B (blue) light-emitting material contained in the luminescent layer B, resulting in the production of white light. The EL material contained in the luminescent layer A causes EL luminescence even when the EL material can cause PL luminescence.

The EL material which emits blue light may be an organic material or an inorganic material. Conventional organic or inorganic materials or organic or inorganic materials which will be developed in the future can be used. The organic EL material may be a polymeric organic EL material or a low-molecular weight organic EL material. The organic EL material generally comprises one or at least two host materials and a luminescent material which is a luminescent compound. When the organic EL material that emits blue light is used, various organic EL materials may be used as the luminescent materials. Examples of such luminescent materials include, but not particularly limited to, those described in working examples which will be described later, for example, 1-tert-butyl-perylene (abbreviated to TBP), TBA (tri(biphenyl-4-yl)amine), and TPB (tetraphenylbutadiene). These materials emit blue light having a peak wavelength of about 470 nm. Also for the host materials, various materials may be used, and examples of such materials include, but not particularly limited to, those described in working examples which will be described later, for example, 9,10-di-2-naphthylanthracene (abbreviated to DNA) and poly[(9,9-di-{5-pentenyl}-fluorenyl-2,7-diyl)-co-(4,4′-(N-(4-sec-butylphenyl))diphenylamine)] (TFB). DNA and Alq3 are an example of coloring matter materials. Alternatively, the host material may also be selected from metal complex materials.

On the other hand, when the organic EL material that emits ultraviolet light is used, for example, triazole derivatives may be mentioned as the luminescent material. Further examples thereof include poly[(9,9-dioctylfluorenyl-2,7-diyl)-co-6,6′-{2,2′-bipyridine})] having a pyridine group as a main chain and polymers having a silane compound as a main chain.

Further, when inorganic nanoparticles are used as the EL material which emits blue light, examples of inorganic nanoparticles usable herein include semiconductor fine particles, the luminescent color of which can be regulated by the particle diameter, and/or dopant-containing semiconductor fine particles. The semiconductor fine particles, the luminescence color of which can be regulated by the particle diameter, are also called quantum dots, nanoparticles, or nanocrystals, and, for example, quantum dots or nanocrystals proposed in documents 1 and 2 may be used. A typical example thereof comprises a core of CdSe, a ZnS shell provided on the outer periphery of the core, and a capping compound provided on the outer periphery of the shell. Other semiconductor fine particles exemplified in the documents and the like may also be used. Since the diameter of inorganic nanoparticles which comprise a core of CdSe and a ZnS shell provided on the outer periphery of the core and emit blue light is in the range of 1 nm to 2 nm, the use of inorganic nanoparticles having a diameter in this range is preferred.

Various semiconductor fine particles which emit blue light may be used as the dopant-containing semiconductor fine particles, and examples of such inorganic nanoparticles which emit blue light include semiconductor fine particles of ZnS doped with Ag, semiconductor fine particles of ZnS doped with Ag, Ga, and Cl, semiconductor fine particles of SrS doped with Cu or Ce, and semiconductor fine particles of Sr₃ (PO₂)₃Cl doped with Eu. Preferably, the diameter of the semiconductor fine particles is, for example, in the range of 1 nm to 100 nm.

On the other hand, also when inorganic nanoparticles are used as the EL material which emits ultraviolet light, as with the EL material which emits blue light, for example, semiconductor fine particles, the luminescent color of which can be regulated by the particle diameter, and/or dopant-containing semiconductor fine particles may be used. Specifically, regarding the semiconductor fine particles, the luminescent color of which can be regulated by the particle diameter, ultraviolet light can be emitted, for example, by regulating the diameter of inorganic nanoparticles having a CdSe/ZnS-type core-shell structure having a basic structure comprising a core of CdSe, a ZnS shell provided on the outer periphery of the core, and a capping compound provided on the outer periphery of the shell, to a range of 0.5 nm to 1.5 nm.

Fundamentally, the inorganic nanoparticles may be an EL luminescent material or alternatively may be a PL luminescent material. That is, any inorganic nanoparticles may be used as long as they, when incorporated in the luminescent layer A, exhibit EL luminescence through the action of excitons produced by recombination of carriers, and the inorganic nanoparticles may be formed of even a material that exhibits PL luminescence.

The mixing ratio of the luminescent material to the host material when the organic EL material is used, and the mixing ratio between the host material and the inorganic nanoparticles when the inorganic nanoparticles are used, may also vary depending upon the type of the material used and cannot be said unconditionally. However, the luminescent material is generally mixed at a weight ratio of about 1 to 20% by weight (% by weight is synonymous with % by mass) to the host material. Further, the thickness of the luminescent layer A is not particularly limited and may be, for example, approximately 5 nm to 200 nm, preferably approximately 20 nm to 100 nm. Further, in the formation of the luminescent layer A, an optimal method dependent upon the type of the EL material used is adopted. When the organic EL material is used, in addition to vapor deposition, for example, coating methods such as spray coating, nozzle jet coating, ink jet coating, spin coating, blade coating, dip coating, cast coating, roll coating, bar coating, or die coating may be adopted.

Inorganic nanoparticles that have been described as an example of semiconductor fine particles, the luminescent color of which can be regulated by the particle diameter, comprising a core of CdSe, a ZnS shell provided on the outer periphery of the core, and a capping compound provided on the outer periphery of the ZnS shell are preferred. When the core-shell structure comprises a core of a semiconductor compound and a shell of a semiconductor compound that is different from the compound constituting the core and has a higher band gap than the semiconductor compound constituting the core, excitons are confined in the core and the capping compound functions as a dispersing agent. Specific examples of such capping compounds include TOPO (tri-n-octylphosphine oxide), TOP (trioctylphosphine), TBP (tributylphosphine), and a triphenylamine group that is commonly used in organic EL and has carrier transportability. These materials have high affinity for the host material, and the inorganic nanoparticles can be evenly dispersed in the host material.

(Luminescent Layer B)

The luminescent layer B is a PL luminescent layer comprising inorganic nanoparticles that emit light by photoluminescence (PL), and, as shown in FIGS. 1 to 6, is held between the semi-transparent reflective layer 5 and the total reflective layer 6. The luminescent layer B contains a PL material and receives light emitted in the luminescent layer A, and, consequently, the PL material emits light. The PL luminescence in the luminescent layer B occurs upon exposure to light emitted by EL luminescence in the luminescent layer A. Specifically, in the PL luminescence, light emitted by EL luminescence is used as an excitation energy source, and luminescence is generated by excitons produced by recombination of photocarriers. When the luminescent layer B is located adjacent to the luminescent layer A and is held between the anode 3 and the cathode 4, in some cases, the PL material undergoes an influence of excitons generated by recombination of carriers (charges) supplied from both the electrodes 3, 4 and exhibits EL luminescence. In any event, however, in the luminescent layer B, the PL material contained in the luminescent layer B emits light having a predetermined color.

As with the luminescent layer A, there are two embodiments about the PL material contained in the luminescent layer B. The first embodiment corresponds to the case where the luminescent layer A contains an organic material and/or inorganic nanoparticles that emit blue light, and, in this case, inorganic nanoparticles which emit red light and inorganic nanoparticles which emit green light are contained as the PL materials in the luminescent layer B. On the other hand, the second embodiment corresponds to the case where the luminescent layer A contains an organic material and/or inorganic nanoparticles that emit ultraviolet light, and, in this case, inorganic nanoparticles which emit blue light, inorganic nanoparticles which emit red light, and inorganic nanoparticles which emit green light are contained as the PL material in the luminescent layer B. In the first embodiment, the luminescent layer A emits blue light which then excites and emits lights from the red light-emitting PL material and the green light-emitting PL material in the luminescent layer B to produce white light. On the other hand, in the second embodiment, the luminescent layer A emits ultraviolet light which then excites and emits lights from the R (red) light-emitting PL material, the G (green) light-emitting PL material, and the B (blue) light-emitting material in the luminescent layer B to produce white light.

As shown in FIG. 2, the luminescent layer B may be provided as a single layer adjacent to the luminescent layer A or alternatively, as shown in FIGS. 3 (I) to (K), may be provided as two layers adjacent respectively to both sides of the luminescent layer A. The luminescent layer B may not be located adjacent to the luminescent layer A, and, for example, any one or two layers of a hole transport layer, an electron injection layer, a hole block layer, and an electron block layer may be interposed between the luminescent layer B and the luminescent layer A. When the luminescent layer B is formed in two or more layers, for example, layers containing respective PL materials of a plurality of colors included in the luminescent layer B can be separately formed and, thus, the production process can be facilitated.

Further, in all of white light emitting elements shown in FIGS. 2 to 4, the luminescent layer B is provided between the opposed electrodes 3, 4. Alternatively, as shown in FIGS. 5 and 6, the luminescent layer B may be provided outside between the opposed electrodes 3, 4. When the luminescent layer B is provided outside between the opposed electrodes 3, 4, as shown in FIG. 5 and FIGS. 6 (N) and (P), one layer when the luminescent layer B is formed of one layer or all of at least two layers constituting the luminescent layer B when the luminescent layer B comprises a plurality of layers may be provided outside between the electrodes 3, 4. As shown in FIG. 6 (Q), a part of layers constituting the luminescent layer B may be provided between the opposed electrodes 3, 4 and another part of the layers constituting the luminescent layer B may be provided outside between the opposed electrodes 3, 4.

When the luminescent layer B is provided outside between the opposed electrodes 3, 4, the thickness of the luminescent layer B can easily be increased. In this case, the thickness of the luminescent layer B can be increased, for example, to approximately 1 μm to 100 μm. Increasing the thickness of the luminescent layer B is advantageous in that, since a large amount of the PL material can be incorporated in the luminescent layer B, color conversion can be reliably realized without use of any color filter. However, the provision of a thick luminescent layer B between the electrodes is disadvantageous in that large applied voltage is necessary when the flow of a given current across the electrodes is contemplated. Accordingly, when the luminescent layer B having a large thickness is provided, preferably, an element structure is adopted in which the luminescent layer B is provided outside between the opposed electrodes 3, 4.

The host material constituting the luminescent layer B varies depending upon the position at which the luminescent layer B is provided. For example, when the luminescent layer B is provided between the luminescent layer A and the anode 3, the host material for constituting the luminescent layer B is a hole transport material. On the other hand, when the luminescent layer B is provided between the luminescent layer A and the cathode 4, the host material for constituting the luminescent layer B is an electron transport material. When the luminescent layer B is provided outside between the opposed electrodes 3, 4, the host material for constituting the luminescent layer B may be, for example, a binder resin material as shown in FIG. 5 and FIG. 6 (P) or alternatively may be, for example, a material for passivation layer formation as shown in FIGS. 6 (N) and (Q). The hole transport material, the electron transport material, the binder resin material, and the material for passivation layer formation referred to herein will be described later.

The inorganic nanoparticles 21, 22 contained in the luminescent layer B may be the same as the inorganic nanoparticles contained in the luminescent layer A independently of the position at which the luminescent layer B is provided. The inorganic nanoparticles 21, 22 are semiconductor fine particles, the luminescent color of which can be regulated by the particle diameter, and/or dopant-containing semiconductor fine particles. In the first embodiment, inorganic nanoparticles which emit red light and inorganic nanoparticles which emit green light are used, and, in the second embodiment, inorganic nanoparticles which emit red light, inorganic nanoparticles which emit green light, and inorganic nanoparticles which emit blue light are used.

For the semiconductor fine particles of which the luminescent color can be regulated by the particle diameter, the inorganic nanoparticles which emit red light may be, for example, inorganic nanoparticles that have a structure comprising a core of CdSe and a ZnS shell provided on the outer periphery of the core and have a diameter in the range of 4 nm to 10 nm. Further, the inorganic nanoparticles which emit green light may be, for example, inorganic nanoparticles that have a structure comprising a core of CdSe and a ZnS shell provided on the outer periphery of the core and have a diameter in the range of 2 nm to 3 nm. The inorganic nanoparticles which emit blue light may be, for example, inorganic nanoparticles that have a structure of a core of CdSe and a ZnS shell provided on the outer periphery of the core and have a diameter in the range of 1 nm to 2 nm.

Further, for the dopant-containing semiconductor fine particles, the inorganic nanoparticles which emit red light may be, for example, semiconductor fine particles of Y₂O₃ doped with Eu and semiconductor fine particles of YVO₄ doped with Eu. The inorganic nanoparticles which emit green light may be, for example, semiconductor fine particles of ZnO doped with Zn, semiconductor fine particles of Zn₃SiO₂ doped with Mn, semiconductor fine particles of Zn₃S doped with Cu and/or Al, semiconductor fine particles of (Zn,Cd)S doped with Cu and/or Al, and semiconductor fine particles of ZnS doped with Cu. The inorganic nanoparticles which emit blue light may be, for example, semiconductor fine particles of ZnS doped with Ag, semiconductor fine particles of ZnS doped with Ag, Ga, and/or Cl, semiconductor fine particles of SrS doped with Cu and/or Ce, and semiconductor fine particles of Sr₃(PO₂)₃Cl doped with Eu.

The mixing ratio of the PL material to the host 3n material constituting the luminescent layer B may also vary depending upon the type of the material used and cannot be said unconditionally but is generally approximately in the range of 1 to 20% by weight (% by weight is synonymous with % by mass). The thickness of the luminescent layer B is set by taking into consideration a balance between the thickness and the color conversion efficiency. In the formation of the luminescent layer B, an optimal method dependent upon the type of the host material and the PL material used is adopted. In general, however, the luminescent layer B is formed by preparing a coating solution for the luminescent layer B and then coating the coating solution by a coating method, for example, spray coating, nozzle jet coating, ink jet coating, spin coating, blade coating, dip coating, cast coating, roll coating, bar coating, or die coating.

As with the luminescent layer A, in the inorganic nanoparticles that have been described as an example of the semiconductor fine particles of which the luminescent color can be regulated by regulating the particle diameter and have a structure comprising a core of CdSe, a ZnS shell provided on the outer periphery of the core, and a capping compound provided on the outer periphery of the ZnS shell, the capping compound is a capping material that has high affinity for the host material and can evenly disperse the inorganic nanoparticles in the host material. Such capping materials include, for example, commonly used trioctylphosphine oxide (TOPO) and a triphenylamine group that is commonly used in organic EL elements and has carrier transportability. The commonly used TOPO has the effect of suppressing the aggregation among the inorganic nanoparticles and the effect of improving the dispersibility of the inorganic nanoparticles in the solution. The triphenylamine group and other groups that have carrier transportability and are generally used in organic EL elements have, for example, the effect of imparting the carrier transportability and the effect of realizing dispersion stability between the capping materials and the binder molecules in the thin film.

Among the inorganic nanoparticles used in the present invention, the semiconductor fine particles, the luminescent color of which can be regulated by the particle diameter, will be further described. The semiconductor fine particles are also called quantum dots and are fine particles, the luminescent color of which can be regulated by regulating the particle diameter, and are preferably used as the inorganic nanoparticles of the present invention. In the following description, such semiconductor fine particles will be referred to as “quantum dots.”

The quantum dots are not particularly limited as long as they are semiconductor fine particles (semiconductor nanocrystals) of nanometer size and are a luminescent material that exhibits a quantum confinement effect (quantum size effect). Specific examples of such luminescent materials include group II-VI semiconductor compounds such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe, group III-V semiconductor compounds such as AlN, AlP, AlAs, AlSb, GaAs, GaP, GaN, GaSb, InN, InAs, InP, InSb, TiN, TiP, TiAs, and TiSb, semiconductor crystals containing group IV semiconductors such as Si, Ge, and Pb, and, further, semiconductor compounds containing three or more elements such as InGaP. Alternatively, semiconductor crystals comprising the semiconductor compound doped with a cation of a rare earth metal or a cation of a transition metal, for example, Eu³⁺, Tb³⁺, Ag⁺, or Cu⁺, may also be used. Among others, semiconductor crystals such as CdS, CdSe, CdTe, or InGaP are suitable from the viewpoints of easiness of preparation, the controllability of the particle diameter which provides luminescence in a visible range, and fluorescence quantum yield.

The quantum dots may be formed of one semiconductor compound or two or more semiconductor compounds. For example, the quantum dots may have a core-shell structure comprising a core formed of a semiconductor compound and a shell formed of a semiconductor compound different from the compound constituting the core. The luminescence efficiency of the core-shell-type quantum dots can be enhanced by using, as a semiconductor compound constituting the shell, a material that has a higher band gap than the semiconductor compound constituting the core so that excitons are confined in the core. Examples of the core-shell structure (core/shell) having a magnitude relation in the band gap between the core and the shell include CdSe/ZnS, CdSe/ZnSe, CdSe/CdS, CdTe/CdS, InP/ZnS, GaP/ZnS, Si/ZnS, InN/GaN, InP/CdSSe, InP/ZnSeTe, GalnP/ZnSe, GalnP/ZnS, Si/AlP, InP/ZnSTe, GalnP/ZnSTe, and GalnP/ZnSSe.

The size of the quantum dots may be properly regulated depending upon the material for constituting the quantum dots to obtain light having a desired wavelength. The energy band gap of the quantum dots increases with reducing the particle diameter of the quantum dots. That is, as the crystal size decreases, the luminescence of the quantum dots shifts toward blue, that is, higher energy. Accordingly, the luminescence wavelength can be regulated over wavelength ranges of an ultraviolet range spectrum, a visible range spectrum, and an infrared range spectrum by varying the size of quantum dots. In general, the particle diameter of the quantum dots is preferably in the range of 0.5 to 20 nm, particularly preferably in the range of 1 to 10 nm. When the size distribution of the quantum dots is narrower, a luminescent color having higher sharpness can be provided.

The shape of the quantum dots is not particularly limited, and the quantum dots may be in a spherical, rod, disk, or other form. When the quantum dots are not spherical, the particle diameter of the quantum dots may be assumed to be the particle diameter of spheres having the same volume as the non-spherical quantum dots. Information about the particle diameter, shape, dispersed state and the like of the quantum dots can be obtained with a transmission electron microscope (TEM). Further, the crystal structure and particle diameter of the quantum dots can be learned from X-ray crystal diffraction (XRD). Furthermore, the particle diameter of the quantum dots and information about the surface of the quantum dots can also be obtained by a UV-Vis absorption spectrum.

(Reflective Layer)

The reflective layer is a layer that resonates light emitted from the EL material within the element and comprises layers that are opposed to each other and hold the luminescent layer A therebetween. The reflective layer comprises a layer that has a total reflection function (a total reflective layer 6) and a layer that has a semi-transparent reflection function (a semi-transparent reflective layer 5). The semi-transparent reflective layer 5 and the total reflective layer 6 may be provided so as to function also as the cathode 4 or the anode 3 or alternatively may be provided as functional layers separately from the cathode 4 or the anode 3. That is, the total reflective layer 6 is provided as one of the opposed electrodes 3, 4 or a layer adjacent to electrode, and the semi-transparent reflective layer 5 is provided as the other electrode or a layer adjacent to the other electrode in the opposed electrodes 3, 4.

The reflective layer is a layer that reflects light emitted in the luminescent layer A to form a resonator structure which will be described later. Accordingly, that the reflective layer (semi-transparent reflective layer 5 and total reflective layer 6) is “formed as a layer adjacent to the electrode” referred to in the present application is defined as such a state that the reflective layer is provided at least on the outer side of the electrodes 3, 4 (a position not on the luminescent layer A side), as such a state that the reflective layer is provided adjacent to and in contact with the electrodes 3, 4, and as such a state that both the reflective layer and the electrodes 3, 4 meet requirements for their respective functions although the luminescent layer B is interposed between the electrodes 3, 4 and the reflective layer, that is, the electrodes 3, 4 and the reflective layer are not in contact with each other. That is, as shown in FIG. 6, a construction may be constructed so that the cathode 4 and the semi-transparent reflective layer 5 are provided through the luminescent layer B so that the semi-transparent reflective layer 5 is located on the light outgoing surface side of the cathode 4. Also in this case, the PL material contained in the luminescent layer B can be excited by light emitted by EL luminescence from the luminescent layer A to emit light. As will be described later, the light emitted by EL luminescence from the luminescent layer A is resonated between the opposed reflective layers to form a luminescence spectrum having a narrow half-value width and to produce white light having high color purity.

Embodiments wherein the total reflective layer 6 is provided so as to function also as the electrode include embodiments as shown, for example, in FIG. 2 (A) wherein the total reflective layer 6 functions also as the cathode 4 and embodiments as shown, for example, in FIG. 3 (E) wherein the total reflective layer 6 functions also as the anode 3. Embodiments wherein the semi-transparent reflective layer 5 is provided so as to function also as the electrode include embodiments as shown, for example, in FIG. 2 (A) wherein the semi-transparent reflective layer 5 functions also as the anode 3 and embodiments as shown, for example, in FIG. 3 (E) wherein the semi-transparent reflective layer 5 functions also as the cathode 4.

On the other hand, embodiments wherein the total reflective layer 6 is provided separately from the electrode include an embodiment as shown in FIG. 3 (F) wherein the anode 3 is provided on the total reflective layer 6. Embodiments wherein the semi-transparent reflective layer 5 is provided separately from the electrode include an embodiment as shown in FIG. 2 (B) wherein the anode 3 is provided on the semi-transparent reflective layer 5, an embodiment as shown in FIG. 2 (C) wherein the semi-transparent reflective layer 5 is provided on the anode 3, an embodiment as shown in FIG. 3 (G) wherein the cathode 4 is provided on the semi-transparent reflective layer 5, and an embodiment as shown in FIG. 3 (H) wherein the semi-transparent reflective layer 5 is provided on the cathode 4.

when the luminescent layer B is provided outside the opposed electrodes 3, 4, as shown in FIG. 5, the semi-transparent reflective layer 5 is provided separately from and on the light outgoing side of the anode 3 through the luminescent layer B, or, as shown in FIGS. 6 (N) to (Q), the semi-transparent reflective layer 5 is provided separately from and on the light outgoing side of the cathode 4 through the luminescent layer B.

In the present invention, the opposed reflective layers (total reflective layer 6 and semi-transparent reflective layer 5) constitute a resonator structure. The resonator structure is a structure in which emitted light can be reflected from opposed reflective layers to cause resonation and to reduce the half-value width of the luminescence spectrum. The reduction in the half-value width of the luminescence spectrum takes place as a result of selective generation of electromagnetic waves with the resonance frequency resonated by the reflection and offers effects such as improved luminescence efficiency and the generation of coherent light. In the resonator structure, a better effect can be attained by bringing the optical distance of the resonance part close to the luminescence wavelength.

In the white light emitting element 1 of the present invention, the optical distance (distance between the semi-transparent reflective layer 5 and the total reflective layer 6) is brought to approximately 230 to 240 nm to resonate a luminescence spectrum of blue light with a wavelength of 460 nm to 480 nm emitted in the luminescent layer A and to reduce the half-value width of the luminescence spectrum, whereby the luminescence spectrum can be tuned to a sharp luminescence spectrum. Thus, regarding the tuning of the luminescence spectrum by the resonance effect, the above resonance effect can be attained by bringing the optical distance to a value equal to or an integer multiple of the wavelength of blue light emitted in the luminescent layer A (for example, twice or thrice), or a half-integer multiple of the wavelength of blue light emitted in the luminescent layer A (for example, 1/2 time or 3/2 times). When a phase shift of 1/2 wavelength occurs in the total reflective layer 6 while a phase shift does not occur in the semi-transparent reflective layer 5, light can be resonated when the optical distance is, for example, 1/4 time, 3/4 time, or 5/4 times the wavelength of the light.

The total reflective layer 6 is preferably a metal layer, and preferred examples thereof include an aluminum layer having a thickness of not less than 100 nm and an Ag layer having a thickness of not less than 50 nm. The reflectance of the total reflective layer 6 is preferably not less than 90%, more preferably not less than 95%. The high reflectance means that the light can be completely reflected, and, thus, the high reflectance is also preferred from the viewpoint of improving light takeout efficiency. When the total reflective layer 6 is provided so as to function also as the anode 3, preferably, a metal that has good hole injectability and large work function, for example, gold or chromium, is selected from the anode materials described above and is provided in a thickness large enough to provide high reflectance. On the other hand, when the total reflective layer 6 is provided so as to function also as the cathode 4, preferably, a metal that has good electron injectability and small work function, for example, alkali metals or alloys of the alkali metals, is selected from the cathode materials described above and is provided in a thickness large enough to provide high reflectance.

On the other hand, the semi-transparent reflective layer 5 is also preferably a metal layer. Preferably, however, the semi-transparent reflective layer 5 has a smaller thickness than the total reflective layer 6 and is, for example, an MgAg layer having a thickness of approximately 5 nm to 15 nm or a Ca layer having a thickness of approximately 5 nm to 20 nm. The reflectance of the semi-transparent reflective layer 5 is preferably not less than 5%, more preferably not less than 10%. When the semi-transparent reflective layer 5 is provided so as to function also as the anode 3, preferably, a transparent electroconductive film or a metal that has good hole injectability and large work function, for example, gold or chromium, is selected from the anode materials described above and is provided in a thickness that provides a reflectance in the above-defined reflectance range. On the other hand, when the semi-transparent reflective layer 5 is provided so as to function also as the cathode 4, preferably, a metal that has good electron injectability and small work function, for example, alkali metals or alloys of the alkali metals, is selected from the cathode materials described above and is provided in a thickness that provides a reflectance in the above-defined reflectance range. The semi-transparent reflective layer may also be a conventional transparent electroconductive film such as an ITO or IZO film although the film has a low reflectance.

(Hole Transport Layer)

The hole transport layer 9 functions to transport holes supplied from the anode 3 to the luminescent layer A and, as shown in FIGS. 2 (D), 4 (L), 5, and 6 (N) and (P), may be provided separately on the anode 3 or the semi-transparent reflective layer 5 provided on the anode 3. The hole transport layer 9, when formed of some materials, can function as an electron block layer that blocks electrons supplied from the cathode 4 to the luminescent layer A. Materials for hole transport layer 9 formation include, for example, arylamine derivatives, anthracene derivatives, carbazole derivatives, thiophene derivatives, fluorene derivatives, distyrylbenzene derivatives, and spiro compounds. When the luminescent layer B is provided between the anode 3 and the luminescent layer A, the hole transport layer 9 may not be provided because the luminescent layer B contains a hole transport material as a host material.

The hole transport layer 9 may be formed by a coating method using a coating solution containing the above material for hole transport layer formation. The thickness of the hole transport layer 9 may vary depending, for example, upon the material used, but is preferably, for example, approximately 1 nm to 50 nm. The hole transport layer 9 may if necessary contains additives such as binder resins, curable resins, and coating improvers.

(Electron Transport Layer)

As shown in the accompanying drawings, the electron transport layer 7 functions to transport electrons supplied from the cathode 4 to the luminescent layer A. Materials for electron transport layer 7 formation include, for example, metal complexes, oxadiazole derivatives, triazole derivatives, phenanthroline derivatives, and silyl compounds. Specific examples thereof include phenanthrolines, for example, bathocuproine or bathophenanthroline; metal complexes, for example, tris(8-quinolinolato)aluminum complex (Alq₃); and oxadiazole derivatives, for example, (2-(4-biphenyl)-1)-5-(4-tert-butylphenyl)-1,3,4-oxadiazole) (PBD).

(Electron Injection Layer)

The electron injection layer 8 functions to facilitate injection of electrons from the cathode 4. Materials for electron injection layer 8 formation include alkali metals, halides of alkali metals, and organic complexes of alkali metals, for example, aluminum, lithium fluoride, strontium, magnesium oxide, magnesium fluoride, strontium fluoride, calcium fluoride, barium fluoride, aluminum oxide, strontium oxide, calcium, sodium polymethylmethacrylate polystyrene sulfonate, lithium, cesium, and cesium fluoride.

(Passivation Layer)

As shown in FIGS. 3 (E) and (F) and FIGS. 4 (I) to (L), when a semi-transparent reflective layer 5 having a small thickness is provided so as to function also as the cathode 4, a passivation layer 10 is optionally provided on the semi-transparent reflective layer 5 to prevent a layer such as an electron transport layer provided on the lower part of the semi-transparent reflective layer 5 from being deteriorated by water vapor or oxygen. Materials for passivation layer 10 formation include SiOx, SiNx, SiCx, parylene and multilayered films of these materials. The thickness may vary depending upon the material for passivation layer 10 formation, and the layer is formed to a thickness large enough to avoid a deterioration in the layer by water vapor or oxygen.

As shown in FIGS. 6 (N) and (Q), when the luminescent layer B is provided outside the opposed electrodes 3, 4, the materials for passivation layer formation are used as the host material for constituting the luminescent layer B. The luminescent layer B is constructed so that inorganic nanoparticles 21, 22 contained in the luminescent layer B are not deteriorated by water vapor or oxygen.

(Protecting Layer 11)

As shown in FIGS. 3 and 6, the protecting layer 11 is provided on the electron injection layer 8. When the cathode 4 is provided on the electron injection layer 8, the protecting layer 11 is provided to reduce damage to the electron injection layer 8. The cathode 4 is provided on the protecting layer 11. Materials for protecting layer 11 formation include inorganic semiconductor materials such as ZnS, organic materials commonly used in organic EL elements, and mixed thin films comprising the organic materials in which an oxidizing agent has been incorporated to improve the electroconductivity. The protecting layer 11 is formed, for example, by a film forming method such as a vapor deposition method, for example, to a thickness of approximately 10 nm to 1000 nm. Further, the thickness of the protecting layer can be utilized to form a semi-transparent reflective layer such as ITO on the upper part of the protecting layer to form a resonator structure.

(Other Layers)

The white light emitting element according to the present invention may if necessary comprise a hole injection layer (not shown) as described in a working example which will be described later. In general, the hole injection layer is preferably provided on the anode 3 and functions to facilitate the injection of holes from the anode 3. Materials usable for hole injection layer formation include those which have hitherto been known as materials for hole injection layer formation, for example, poly(3,4)ethylenedioxythiophene/polystyrenesulfonate (abbreviated to PEDOT/PSS, manufactured by Bayer Co. Ltd., tradename; Baytron P AI4083, commercially available as an aqueous solution).

If necessary, a hole block layer may also be provided. The hole block layer functions to prevent holes injected from the anode 3 from going through the luminescent layer A and thus to increase the opportunity of recombination between the holes and electrons within the luminescent layer A. Materials for hole block layer formation include, for example, (2-(4-biphenyl)-1)-5-(4-tert-butylphenyl)-1,3,4-oxadiazole) (PBD).

As described above, according to the white light emitting element 1 of the present invention, light emitted by EL luminescence in the luminescent layer A can be resonated between the layer having a total reflection function and the layer having a semi-transparent reflection layer to reduce the half-value width of the luminescence spectrum, and, thus, white light produced using lights emitted by respective types of luminescences has high color purity. Even when the EL material contained in the luminescent layer A exhibits PL luminescence, the emitted light exhibits a luminescence spectrum having a narrow half-value width, and, thus, also in this case, white light having high color purity can be obtained.

Further, according to the white light emitting element 1 of the present invention, unlike the prior art technique, an EL material of three primary colors of RGB is not contained in the luminescent layer A, and, further, a stable PL material is contained in the luminescent layer B. Accordingly, the color of the white light having high color purity can easily be adjusted, for example, by regulating, for example, the content of the PL material contained in the luminescent layer B or regulating the thickness of the layer having the semi-transparent reflection function. Further, since a single color of a blue EL material having a significant task of providing a prolonged lifetime is used while other colors are emitted by stable PL materials, the lifetime of the whole element can be prolonged.

The white light emitting element 1 according to the present invention can be used as a white light source panel such as lighting, as an RGB light emitting panel that has high color purity through a combination with a color filter, or as a backlight for LCD-OLED or LCD-LED.

### EXAMPLES

The present invention is further illustrated by the following Examples and Comparative Examples that are not intended as a limitation of the invention. In the following Examples, evaluations were carried out by the following evaluation methods.

(1) Measurement of layer thickness: Unless otherwise specified, the thickness of each of the layers according to the present invention was determined by forming each layer having a single layer structure on a cleaned glass substrate with ITO (manufactured by Sanyo Vacuum Industries Co., Ltd.), and measuring the thickness of the formed difference in level. The layer thickness was measured with a probe microscope (Nanopics1000, manufactured by SII NanoTechnology Inc.).

(2) Current efficiency and power efficiency of white light emitting elements: The current efficiency and lifetime properties of the white light emitting elements produced in Example were evaluated. The current efficiency and the power efficiency were calculated by current-voltage-brightness (I-V-L) measurement. I-V-L measurement was carried out by connecting the cathode to ground and applying a positive direct current voltage to the anode while scanning at 100 mV intervals (1 sec./div.) to record current and brightness at each voltage. The brightness of each of R, G, and B shown in Table 1 was measured with a luminance meter BM-8 manufactured by TOPCON CORPORATION. Based on the results thus obtained, the luminescence efficiency (cd/A) was calculated from the luminescent area, current, and brightness. The results thus obtained are shown in Tables 1. The voltages shown in Table 1 are indicated using current-voltage-brightness (I-V-L) measured values. The brightness half-time was obtained based on values measured by drive at a constant current.

(3) Measurement of chromaticity: The chromaticity of the whole element and the chromaticity of each of R, G, and B shown in Table 1 were evaluated by a ΔE94 color difference formula (CIE 1994). The chromaticity was determined by measuring a luminescence spectrum of a white light emitting element with a spectroradiometer SR-2 manufactured by TOPCON CORPORATION and calculating the chromaticity with the above device. The chromaticity after the deterioration was measured after a half reduction in brightness due to the measurement of lifetime properties of a measuring sample.

(4) Measurement of fluorescence spectrum: The fluorescence spectrum was measured with a spectrophotofluorometer F-4500 manufactured by Hitachi. A film having a single-layer structure was formed from a material, to be measured, on glass and measuring a fluorescence spectrum obtained at an excitation light wavelength of 360 nm with a spectrophotofluorometer. The fluorescence spectrum was utilized for determination of EL luminescent spectrum components.

(5) Brightness of RGB components: A luminescence spectrum of the white light emitting element was measured followed by deconvolution based on the fluorescent spectrum to calculate the brightness of each component.

### Example 1

A transparent anode, a hole injection layer, a luminescent layer B comprising inorganic nanoparticles contained in a hole transport material, a hole transport layer, a luminescent layer A that exhibits blue EL, a hole block layer, an electron transport layer, an electron injection layer, and a cathode were formed and stacked in that order on a glass substrate, and the assembly was finally sealed to produce a white light emitting element. All of works except for a transparent anode and a hole injection layer were carried out within a glove box of which the atmosphere was replaced by nitrogen (moisture concentration and oxygen concentration in glove box: not more than 0.1 ppm and not more than 0.1 ppm, respectively).

At the outset, a thin film (thickness: 150 nm) of indium tin oxide (ITO) was formed as a transparent anode. A glass substrate with ITO (manufactured by Sanyo Vacuum Industries Co., Ltd.) was patterned in a strip form. The patterned ITO substrate was ultrasonically cleaned with a neutral detergent and ultrapure water in that order and was subjected to UV ozone treatment.

Ag was then vapor deposited to a thickness of 10 nm on the cleaned anode to form a semi-transparent reflective layer.

A thin film (thickness: 120 nm) of poly(3,4-ethylenedioxythiophene)-polystyrene sulfonic acid (PEDOT-PSS) was formed as a hole injection layer on the semi-transparent reflective layer 5. AI4083 manufactured by H.C. Starck Ltd. was used as PEDOT-PSS. A PEDOT-PSS solution was spin coated in the air to form a coating. After the formation of the PEDOT-PSS film, the PEDOT-PSS film was dried on a hot plate in the air to evaporate moisture.

A luminescent layer B comprising a hole transport material containing inorganic nanoparticles which exhibit red PL and inorganic nanoparticles which exhibit green PL was then formed on the hole injection layer. In this case, poly[(9,9-di-{5-pentenyl}-fluorenyl-2,7-diyl)-co-(4,4′-(N-(4-sec-butylphenyl))diphenylamine)] (TFB) was used as the hole transport material which is a host material of the luminescent layer B, and two inorganic nanoparticles were used as the luminescent material. A mixed thin film (thickness: 40 nm) composed of the hole transport material and the luminescent material was formed as the luminescent layer by a coating method. The mixed thin film was formed by dissolving TFB, inorganic nanoparticles which exhibit green PL, and inorganic nanoparticles which exhibit red PL in toluene at a weight ratio of 5:1:1 to give a coating solution, and coating the coating solution in the air by a spin coating method. TFB was one manufactured by American Dye Source, Inc., and the inorganic nanoparticles which exhibit green EL (particle diameter 2.4 nm) and inorganic nanoparticles which exhibit red PL (particle diameter 5.2 nm) were the so-called quantum dot (also known as QD) material manufactured by Evident Technologies, Inc. After the formation of the mixed film, the film was dried on a hot plate in the air to evaporate toluene.

A thin film (thickness: 5 nm) was then formed as the hole transport layer using bis(N-(1-naphthyl-N-phenyl)benzidine) (α-NPD) on the luminescent layer B. The film was formed by a resistance heating vapor deposition method in vacuo (pressure: 1×10⁻⁴ Pa).

A thin film (thickness: 40 nm) of 9,10-di-2-naphthylanthracene (DNA) containing 1-tert-butyl-perylene (TBP) as a material which emits blue light at a wavelength of 470 nm was then formed as the luminescent layer A on the hole transport layer. DNA and TBP were co-deposited at a ratio of 20:1 by in vacuo (pressure: 1×10⁻⁴ Pa) by a resistance heating vapor deposition method to form a thin film thickness: 40 nm)

Bis(2-methyl-8-quinolilate)(p-phenylphenolate)aluminum complex (abbreviated to BAlq) (thickness: 10 nm) was then formed as a hole block layer on the luminescent layer A. The hole block layer was formed by a resistance heating vapor deposition method in vacuo (pressure: 1×10⁻⁴ Pa).

Tris(8-quinolinolato)aluminum complex (Alq3) (thickness: 20 nm) was then formed as an electron transport layer on the hole block layer. The hole block layer was formed by a resistance heating vapor deposition method in vacuo (pressure: 1×10⁻⁴ Pa).

A film of LIF (thickness: 0.5 nm) was then formed on the electron transport layer as an electron injection layer, and Al (thickness: 120 nm) was further formed as a cathode, on the LIF film, which functions also as the total reflection layer. The films were formed by a resistance heating vapor deposition method in vacuo (pressure: 1×10⁻⁴ Pa). Finally, after the cathode formation, the assembly was sealed using an alkali-free glass and a UV curing-type epoxy adhesive within a glove box to produce a white light emitting element of Example 1 having a bottom emission-type element structure.

### Example 2

A white light emitting element of Example 2 having a bottom emission-type element structure was produced in the same manner as in Example 1, except that the thickness of the luminescent layer B was changed to 100 nm and, further, the thickness of the hole injection layer was changed to 60 nm.

### Example 3

A white light emitting element of Example 3 having a bottom emission-type element structure was produced in the same manner as in Example 1, except that the thickness of the luminescent layer B was changed to 100 nm, the luminescent layer B was formed using a PL material in which a triphenylamine group was used instead of TOPO as the capping compound in the inorganic nanoparticles contained in the luminescent layer B, and the thickness of the hole injection layer was changed to 60 nm.

### Example 4

A white light emitting element of Example 4 having a top emission-type element structure was produced in the same manner as in Example 1, except that a laminated film having a construction of ITO (thickness: 10 nm)/Ag (thickness: 100 nm) having a total reflection function/ITO (thickness: 10 nm) was used, instead of the transparent anode (ITO), as an anode that functions also as the total reflection layer, the luminescent layer B was formed using a PL material in which a triphenylamine group was used instead of TOPO as the capping compound in the inorganic nanoparticles contained in the luminescent layer B, the thickness of the luminescent layer B was changed to 100 nm, and Ca (thickness: 15 nm) as a semi-transparent reflective cathode, NPD (thickness: 235 nm) as a protective layer, and IZO (thickness: 150 nm) as a second semi-transparent reflective layer were formed in that order on LIF (thickness: 0.5 nm) as the electron injection layer.

### Comparative Example 1

A white light emitting element of Comparative Example 1 having a bottom emission-type element structure was produced in the same manner as in Example 1, except that Ag having a thickness of 10 nm which functions as the semi-transparent reflective layer was not formed.

### Comparative Example 2

A white light emitting element of Comparative Example 2 having a bottom emission-type element structure was produced in the same manner as in Example 1, except that, in the formation of the luminescent layer B, 2,3,6,7-tetrahydro-1,1,7,7-tetramethyl-1H,5H,11H-10-(2-benzo thiazolyl)quinolizino-[9,9a,1gh]coumarin (abbreviated to C545T) which is a green organic fluorescent material was used instead of the inorganic nanoparticles which exhibit green luminescence and constitute the luminescent layer B, and, further, 9-diethylaminobenzo[a]phenoxazole (abbreviated to NileRed) which is a red organic fluorescent material was used instead of the inorganic nanoparticles which exhibit red luminescence.

(Results of Evaluation)

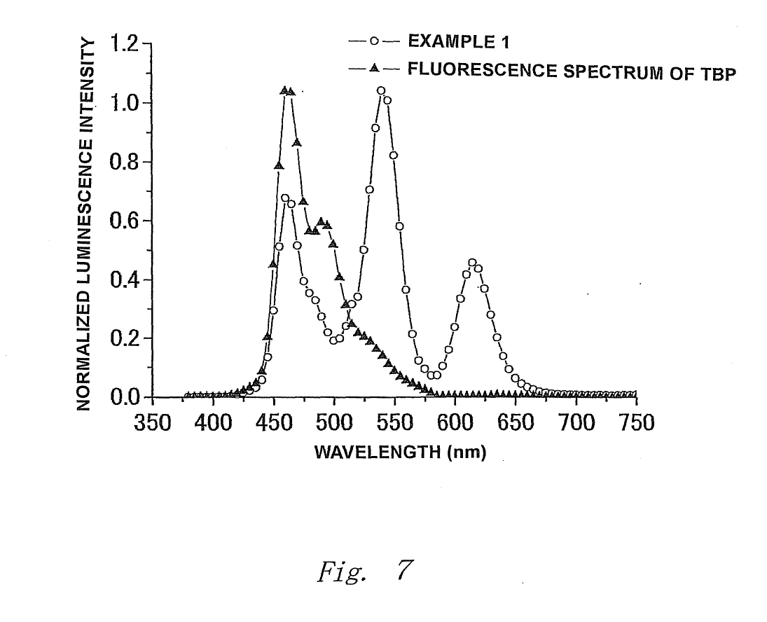

FIG. 7 is a graph showing a luminescence spectrum obtained from the white light emitting element of Example 1 and a fluorescent spectrum for only the blue luminescent material (TBP) used in the luminescent layer A in Example 1. As can be seen from FIG. 7 showing the luminescence spectrum obtained in the white light emitting element produced in Example 1, blue light generated by EL undergoes color conversion in the luminescent layer B, and, consequently, red light and green light are emitted. Further, in the luminescent spectrum obtained from the white light emitting element produced in Example 1, the half-value width of the spectrum for the blue light is smaller than that of the fluorescent spectrum for only the blue luminescent material (TBP).

Table 1 shows the chromaticity, the luminescence efficiency, the voltage, the chromaticity and brightness of each of R, G, and B, the brightness half-time, and the chromaticity after deterioration treatment for the white light emitting elements produced in Examples 1 to 4 and Comparative Examples 1 and 2.

TABLE 1

| | Initial properties (100 cd/m² during luminescence) | | | | | | | | | | |
|---|---|---|---|---|---|---|---|---|---|---|---|
| | Whole element | | | | | | | | | | |
| | | Luminescence | | R | | G | | B | | Brightness | Chromaticity |
| | Chroma- | efficiency | Voltage | Chroma- | Brightness | Chroma- | Brightness | | Brightness | half-time | (after |
| | ticity | (cd/A) | (V) | ticity | (cd/m²) | ticity | (cd/m²) | Chromaticity | (cd/m²) | (hr) | deterioration) |
| Ex. 1 | 0.25, 0.28 | 3.9 | 5.5 | 0.66, 0.34 | 19 | 0.26, 0.71 | 49 | 0.13, 0.14 | 32 | 12 | 0.25, 0.28 |
| Ex. 2 | 0.25, 0.28 | 4.1 | 15 | 0.66, 0.34 | 20 | 0.26, 0.71 | 51 | 0.14, 0.20 | 29 | 10 | 0.25, 0.28 |
| Ex. 3 | 0.25, 0.28 | 4.3 | 10 | 0.66, 0.34 | 20 | 0.26, 0.71 | 51 | 0.14, 0.20 | 29 | 11 | 0.25, 0.28 |
| Ex. 4 | 0.25, 0.28 | 3.9 | 10 | 0.66, 0.34 | 20 | 0.26, 0.71 | 51 | 0.13, 0.13 | 29 | 12 | 0.25, 0.28 |
| Comp. | 0.24, 0.28 | 4.2 | 5.1 | 0.66, 0.34 | 20 | 0.26, 0.71 | 30 | 0.14, 0.19 | 50 | 16 | 0.25, 0.29 |
| Ex. 1 | | | | | | | | | | | |
| Comp. | 0.25, 0.28 | 2.0 | 8 | 0.64, 0.35 | 20 | 0.24, 0.56 | 30 | 0.14, 0.19 | 5 | 6 | 0.25, 0.24 |
| Ex. 2 | | | | | | | | | | | |

For the white light emitting elements produced in the Examples and the Comparative Examples, the brightness and chromaticity of each of the components were calculated based on luminescence spectra obtained by spectrum measurement. As a result, it was found that, as shown in Table 1, the white light emitting element produced in Example 1 had higher color purity of the spectrum for blue due to a resonator effect and exhibited a broader RGB color reproduction range than the white light emitting element produced in Comparative Example 1. Further, as shown in Table 1, the white light emitting element of Example 1 had higher color purity of R and G than the white light emitting element produced in Comparative Example 2 using the low-molecular weight organic material. Furthermore, as shown in Table 1, the white light emitting elements produced in Examples 1 to 4 using the so-called QD had a prolonged lifetime and caused no significant color shift after the measurement of the lifetime. Accordingly, in producing a full-color display using a color filter of RGB, the use of the white light emitting element according to the present invention can realize the formation of pixels that have high color purity, high efficiency, and a further prolonged lifetime.

For the white light emitting element of Example 2 having a large luminescent layer B thickness of 100 nm, as is apparent from Table 1, the proportions of R and G luminescent components are increased, indicating that the percentage color conversion by the luminescent layer B can be improved by adopting a large thickness in the luminescent layer B.

For the white light emitting element of Example 3 in which the thickness of the luminescent layer B was 100 nm and inorganic nanoparticles having hole transport properties were used as the capping compound in the so-called QD could realize lower voltage than the white light emitting element of Example 2.

Further, even for the white light emitting element of Example 4 in which the thickness of the luminescent layer B was 100 nm and the element structure was of a top emission type, R and G luminescent spectrum components were observed, indicating that the percentage color conversion by the luminescent layer B can be improved by adopting a large thickness in the luminescent layer B.

1. A white light emitting element comprising: opposed electrodes, a luminescent layer A comprising an organic material and/or inorganic nanoparticles that emit light by electroluminescence (EL), a luminescent layer B comprising inorganic nanoparticles that emit light by photoluminescence (PL), and opposed reflective layers that allow light emitted in the luminescent layer A to resonate within the element, wherein the white light emitting element produces white light by light emitted in the luminescent layer A and light emitted in the luminescent layer B together;
wherein one of the opposed electrodes or a layer adjacent to the electrodes has a total reflection function and is provided as one of the reflective layers; and
wherein the other electrode or a layer adjacent to the other electrode has a semi-transparent reflection function and is provided as the other reflective layer.

2. The white light emitting element according to claim 1, wherein the electrode or adjacent layer having a semi-transparent reflection function is provided to change a luminescence spectrum of light emitted from the luminescent layer A to a luminescence spectrum having a narrower half-value width.

3. The white light emitting element according to claim 1, wherein the luminescent layer A comprises an organic material that emits blue light and/or inorganic nanoparticles that emit blue light, and
the luminescent layer B comprises inorganic nanoparticles that emit red light and inorganic nanoparticles that emit green light.

4. The white light emitting element according to claim 1, wherein the luminescent layer A comprises an organic material that emits ultraviolet light and/or inorganic nanoparticles that emit ultraviolet light, and
the luminescent layer B comprises inorganic nanoparticles that emit blue light, inorganic nanoparticles that emit red light, and inorganic nanoparticles that emit green light.

5. The white light emitting element according to claim 4, wherein the electrode or adjacent layer having the semi-transparent reflection function is provided to reduce a luminescence spectrum of light emitted from the luminescent layer A and thus to reduce the outgoing efficiency.

6. The white light emitting element according to claim 1, wherein the inorganic nanoparticles are semiconductor fine particles, of which the luminescent color can be regulated by regulating the particle diameter of the semiconductor fine particles, and/or dopant-containing semiconductor fine particles.

7. The white light emitting element according to claim 1, wherein the luminescent layer A and the luminescent layer B each are formed of one layer or at least two layers.

8. The white light emitting element according to claim 1, wherein, when the reflective layer having the semi-transparent reflection function is provided as a layer adjacent to the electrode, the electrode and the reflective layer are provided through the luminescent layer B.

9. The white light emitting element according to claim 1, wherein one or more layers of the reflective layer having the semi-transparent reflection function is provided between the opposed electrodes and/or outside the electrodes.

10. The white light emitting element according to claim 1, wherein the electrode or adjacent layer having the semi-transparent reflection function is provided so as not to reduce the emission of light from the luminescent layer B.

11. The white light emitting element according to claim 1, which has a top emission-type element structure or a bottom emission-type element structure that takes out the white light from the white light emitting element on its side where the layer having the semi-transparent reflection function is provided.
